(19) United States
(12) Patent Application Publication
(10) Pub. No.: US 2021/0167007 A1
(43) Pub. Date: Jun. 3, 2021

(54) REDISTRIBUTION STRUCTURE AND SEMICONDUCTOR PACKAGE INCLUDING THE SAME

(71) Applicant: SAMSUNG ELECTRONICS CO., LTD., SUWON-SI (KR)

(72) Inventors: HYUNSOO CHUNG, SUWON-SI (KR); TAEWON YOO, SUWON-SI (KR); MYUNGKEE CHUNG, SUWON-SI (KR)

(21) Appl. No.: 16/931,129

(22) Filed: Jul. 16, 2020

(30) Foreign Application Priority Data
Nov. 28, 2019 (KR) 10-2019-0156108

(51) Int. Cl. H01L 23/528; H01L 23/532; H01L 23/522; H01L 23/00

(52) U.S. Cl. CPC H01L 23/528; H01L 24/14; H01L 23/5226; H01L 23/53214

(57) ABSTRACT

A semiconductor package includes an electrode pad arranged in a first direction parallel to an upper surface of a semiconductor chip, a first protective layer at least partially surrounding an edge of the electrode pad and having a first opening that is above the electrode pad, a second protective layer at least partially surrounding the first protective layer and having a second opening that is above the electrode pad, and a redistribution structure electrically connected to the electrode pad and covering at least a part of an upper surface of the second protective layer. A first width of the first opening in the first direction is equal to or greater than a maximum width of the redistribution structure in the first direction, and a second width of the second opening in the first direction is less than the maximum width of the redistribution structure in the first direction.

### CROSS-REFERENCE TO RELATED APPLICATION

This patent application claims priority under 35 U.S.C. § 119 to Korean Patent Application No. 10-2019-0156108, filed on Nov. 28, 2019, the disclosure of which is incorporated herein in its entirety by reference.

### TECHNICAL FIELD

The present disclosure relates to a semiconductor package, and more particularly, to a semiconductor package including a redistribution structure.

### DISCUSSION OF THE RELATED ART

With the rapid development of the electronics industry and based on users' need, electronic devices have become more compact and multi-functional. Miniaturization and multi-functionalization of semiconductor chips used, on electronic devices also become increasingly popular. Accordingly, a semiconductor chip including a fine pitch connection terminal is provided, and a small size electrode pad is implemented to mount a high-capacity semiconductor chip in a restrictive structure of a semiconductor package. Hence, a distance between electrode pads included in the semiconductor package can be reduced.

### SUMMARY

The embodiments of the present inventive concept provide a semiconductor package in which redistribution structures may be easily formed by further forming a second protective layer surrounding a first protective layer on an electrode pad and by increasing a distance between the redistribution structures.

The inventive concept is not limited to the concept described above, and other concepts not described will be apparently understood by those skilled in the art from the following description.

According to an exemplary embodiment of the inventive concept, a semiconductor package includes an electrode pad arranged in a first direction parallel to an upper surface of a semiconductor chip, a first protective layer at least partially surrounding an edge of the electrode pad and having a first opening that is above the electrode pad, a second protective layer at least partially surrounding the first protective layer and having a second opening that is above the electrode pad, and a redistribution structure electrically connected to the electrode pad and covering at least a part of an upper surface of the second protective layer. A first width of the first opening in the first direction is equal to or greater than a maximum width of the redistribution structure in the first direction, and a second width of the second opening in the first direction is less than the maximum width of the redistribution structure in the first direction.

According to an exemplary embodiment of the inventive concept, a semiconductor package includes a plurality of aluminum pads arranged on a semiconductor chip and spaced apart from each other with a first pitch therebetween in a first direction; a first polymer layer at least partially surrounding edges of the aluminum pads and having first openings respectively formed above the aluminum pads; a second polymer layer at least partially surrounding the first polymer layer and having second openings respectively formed above the aluminum pads; metal seed layer conformally covering upper surfaces of the aluminum pads, side surfaces of the second polymer layer, and a part of upper surfaces of the second polymer layer; redistribution pads spaced apart from each other with the first pitch and conformally covering the metal seed layers and redistribution lines extending from one side surface of the redistribution pads and each having a line shape. A first width of the first opening in the first direction is greater than a maximum width of the redistribution pad in the first direction, and a second width of the second opening in the first direction is less than the maximum width of the redistribution pad in the first direction.

According to an exemplary embodiment of the inventive concept, a semiconductor package includes a semiconductor chip comprising an electrode pad arranged in a first direction; a redistribution region arranged under the semiconductor chip; a molding member extending from the redistribution region and at least partially surrounding the semiconductor chip; and an external connector arranged under the redistribution region. The redistribution region includes a first protective layer at least partially surrounding an edge of the electrode pad and having a first opening above the electrode pad; a second protective layer at least partially surrounding the first protective layer and having a second opening above the electrode pad; and a redistribution structure electrically connected to the electrode pad and covering at least a part of an upper surface of the second protective layer. A first width of the first opening in the first direction is equal to or greater than a maximum width of the redistribution structure in the first direction. A second width of the second opening in the first direction is less than the maximum width of the redistribution structure in the first direction.

### BRIEF DESCRIPTION OF THE DRAWINGS

The above and other features of the inventive concept will become more apparent)y describing in detail exemplary embodiments thereof with reference to the accompanying drawings, in which:

FIG. 1 is a cross-sectional view illustrating a semiconductor package according to an exemplary embodiment of the inventive concept;

FIG. 2A is a plan view at level LV1 of FIG. 1, and FIG. 2B is a cross-sectional view taken along line B-B′ of FIG. 2A;

FIG. 3A is a plan view illustrating a semiconductor package according to an exemplary embodiment of the inventive concept, and FIG. 3B is a cross-sectional view taken along the line B-B′ of FIG. 3A;

FIG. 4A is a plan view illustrating a semiconductor package according to an exemplary embodiment of the inventive concept, and FIG. 4B is a cross-sectional view taken along the line B-B′ of FIG. 4A;

FIG. 5 is a flowchart illustrating a method of manufacturing a semiconductor package, according to an exemplary embodiment of the inventive concept;

FIGS. 6 to 13 are cross-sectional views illustrating a method of manufacturing a semiconductor package, according to an exemplary embodiment of the inventive concept and a process sequence; and

FIG. 14 is a configuration diagram schematically illustrating a configuration of a semiconductor package according to an exemplary embodiment of the inventive concept.

### DETAILED DESCRIPTION OF THE EMBODIMENTS

Herein, it will be understood that when an element or layer is referred to as being “on”, “connected to” or “coupled to” another element or layer, it can be directly on, connected or coupled to the other element or layer, or intervening elements or layers may be present.

Like reference numerals may refer to like elements throughout this specification. In the figures, the thicknesses of layers, films or regions may be exaggerated for clarity.

As used herein, the singular forms, “a”, “an” and “the” are intended to include the plural forms as well, unless the context clearly indicates otherwise.

Hereinafter, exemplary embodiments of the inventive concept will be described in detail with reference to the accompanying drawings.

With the rapid development in the electronics industry and according to users' need, electronic devices are becoming more compact and multi-functional. Accordingly, miniaturization and multi-functionalization of semiconductor chips used on electronic devices become increasingly popular. Accordingly, a semiconductor chip including connection terminals having a fine pitch is needed, and a small size electrode pad is provided to mount a high capacity semiconductor chip in a restrictive semiconductor package structure. Hence, a distance between the electrode pads included in the semiconductor package also decreases continuously.

In a general semiconductor package, when the number of signal terminals for miniaturization or input and output of a semiconductor chip increases, it is difficult to accommodate all signal terminals on a main surface of the semiconductor chip. Accordingly, in the general semiconductor package, a redistribution structure may extend outside the main surface of the semiconductor chip to expand a region where the signal terminal is arranged. That is, a fan-out wafer level package (FO-WLP) structure or a fan-out panel level package (FO-PLP) (hereinafter, referred to as FO-WLP) structure is applied to the general semiconductor package.

Accordingly, in a semiconductor package having a general FO-WLP structure, an external connection terminal may be arranged on art expanded surface of the semiconductor package by forming a redistribution structure on an electrode pad. In addition, there are characteristics in which a location of the electrode pad and a location in which the external connection terminal is formed may be changed through the redistribution structure.

According to exemplary embodiments of the inventive concept, a redistribution structure of a semiconductor package may be more easily formed by forming a second protective layer surrounding a first protective, layer on an upper surface of an electrode pad and designing a distance between the redistribution structures adjacent to each other to be further increased. In addition, a test process for a semiconductor chip is performed in a step prior to forming the second protective layer after the first protective layer is formed. Thus, an open region of the electrode pad needed in the test process may be obtained. Additionally, the semiconductor package, according to an exemplary embodiment of the inventive concept, may contribute to an increase in reliability of the FO-WLP structure because a thickness of a buffer layer disposed under the redistribution structure is increased. In other words, not only the first protective layer but also the second protective layer are disposed under the redistribution structure, and thus, a thickness of a buffer layer is increased which may reduce a physical difference such as a coefficient of thermal expansion between the external device and the semiconductor chip. Accordingly, structural reliability of the semiconductor package may be increased.

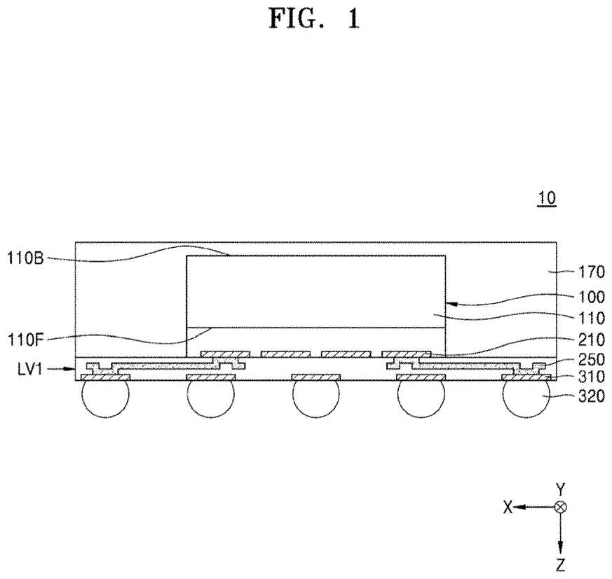

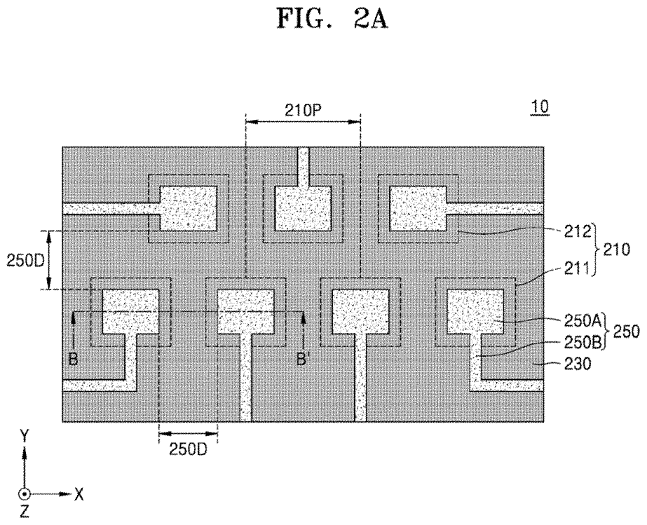

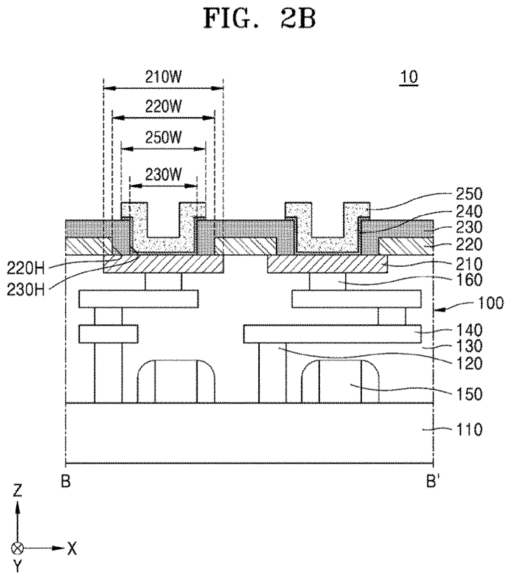

FIG. 1 is a cross-sectional view illustrating a semiconductor package according to an exemplary embodiment of the inventive concept, FIG. 2A is a plan view at level LV1 of FIG. 1, and FIG. 2B is a cross-sectional view taken along line B-B′ of FIG. 2A.

FIGS. 1 to 2B illustrate an electrode pad 210 arranged on an upper surface of a semiconductor chip 100, a first protective layer 220 surrounding edges of the electrode pad 210, a second protective layer 230 surrounding the first protective layer 220, and a redistribution structure 250 electrically connected to the electrode pad 210.

The semiconductor chip 100 may include a semiconductor element. For example, the semiconductor chip 100 may include a semiconductor substrate 110 comprising an active surface 110F and an inactive surface 1108 facing each other. A circuit portion for implementing an integrated circuit function of the semiconductor chip 100 may be formed on the active surface 110F of the semiconductor substrate 110 by a semiconductor manufacturing process. In other words, a wiring, layer such as a conductive via 120, a conductive wire 140, and an upper via 160 (as illustrated in FIG. 2B), and an interlayer insulating film 130 arranged therebetween, and an individual unit element 150 may be formed on the semiconductor substrate 110. In addition, the semiconductor chip 100 may include the electrode pad 210 formed on the semiconductor substrate 110 to be able to extend a function of the circuit portion to the outside. For purpose of convenience and clarity, a surface on which the electrode pad 210 is formed may be referred to as an upper surface of the semiconductor chip 100.

The semiconductor chip 100 may include a logic chip or a memory chip. The logic chip may include, for example, a microprocessor, an analog element, or a digital signal processor. In addition, the memory chip may include, for example, a volatile memory chip such as dynamic random access memory (DRAM) or static RAM (SRAM), or a nonvolatile memory chip such as phase-change RAM (PRAM), magnetoresistive RAM (MRAM), resistive RAM (RRAM), or ferroelectric RAM (FeRAM). In some exemplary embodiments of the inventive concept, the semiconductor chip 100 may include a high bandwidth memory.

As illustrated in FIGS. 1 and 2B, a molding member 170 may protect the semiconductor chip 100 from external influences such as contamination and impact. To achieve this goal, the molding member 170 may be formed of an epoxy mold compound, a resin, etc. In addition, the molding member 170 may be formed by a process such as compression molding, lamination, screen printing, etc. In some exemplary embodiments, the molding member 170 may cover only a side surface of the semiconductor chip 100 to expose a lower surface of the semiconductor chip 100 to the outside. The molding member 170 may define an external shape of the semiconductor package 10, and the redistribution structure 250 may be arranged using the molding member 170.

The electrode pad 210 may be electrically connected to the individual unit element 150 through the upper via 160 to electrically connect a function of the circuit portion of the semiconductor chip 100 to an external connection member 320 attached to an external connection pad 310. In some exemplary embodiments of the inventive concept, the electrode pad 210 may include an aluminum (Al) pad.

In the electrode pad 210, a peripheral portion thereof may be covered by the first protective layer 220 and the second protective layer 230 formed on the active surface 110F of the semiconductor substrate 110, and a central portion thereof may be exposed. Although the electrode pad 210 is illustrated in the accompanying drawings as having a quadrangular shape, for example, the electrode pad 210 may be a polygon such as a hexagon or an octagon or may be a circle or an ellipse. The electrode pad 210 may have at least a specified size to withstand electrical or mechanical stress.

In addition, the electrode pad 210 may include a first column electrode pad 211 and a second column electrode pad 212 spaced apart from the first column electrode pad 211 in a second direction (Y direction). The electrode pads 210 may be spaced apart from each other to have a first pitch 210P in a first direction (X direction) and a second direction (Y direction) parallel to the upper surface of the semiconductor chip 100. The first pitch 210P may be approximately 50 μm to approximately 70 μm. In some cases, the first pitch 210P may be approximately 60 μm.

As illustrated in FIG. 2B, the first protective layer 220 may be arranged on the upper surface of the semiconductor chip 100 such that the semiconductor chip 100 is insulated in a region other than the electrode pad 210. In addition, the first protective layer 220 may surround an edge of the electrode pad 210 and have a first opening 220H having a first width 220W above the electrode pad 210. For example, the first protective layer 220 may have a bridge shape connecting the electrode pads 210 adjacent to each other. In some exemplary embodiments of the inventive concept, the first protective layer 220 may be formed of an insulating material that is highly flexible and insulative.

In an exemplary embodiment of the inventive concept, the first width of the first opening maybe approximately 40 μm.

In some exemplary embodiments of the inventive concept, the first protective layer 220 may be formed of a polymer, benzocyclobutene, or resin. In some cases, the first protective layer 220 may be formed of photosensitive polyimide. Accordingly, the first protective layer 220 may be referred to as a first polymer layer. However, a material forming the first protective layer 220 is not limited thereto. For example, the first protective layer 220 may be formed of silicon-based silicon oxide or silicon nitride.

In addition, the first, protective layer 220 may protect the upper surface of the semiconductor chip 100 from external impurities, chemical damage, physical impact, and etc. Accordingly, after the first protective layer 220 is formed on the semiconductor chip 100, a test process is performed over the semiconductor chip 100. Details thereof will be described below.

The second protective layer 230 surrounds the first protective layer 220 and has a second opening 230H having a second width 230W above the electrode pad 210. The second protective layer 230 may cover an entirety of a side surface and an entirety of an upper surface of the first protective layer 220. Accordingly, a level of an uppermost surface of the second protective, layer 230 may be higher than a level of an uppermost surface of the first protective layer 220. For example, a lower surface of the second protective layer 230 may be on top of or directly above an upper surface of the first protective layer 220. The lower surface of the second protective layer 230 may be in contact with the upper surface of the first protective layer 220.

The second protective layer 230 may also be formed of an insulating material in the same manner as the first protective layer 220. The second protective layer 230 may be formed of a polymer, benzocyclobutene, or resin, and particularly, may be formed of photosensitive polyimide. Accordingly, the second protective layer 230 may be referred to as a second polymer layer. In some exemplary embodiments, the second protective layer 230 may be formed of a material different from a material of the first protective layer 220. For example, both the second protective layer 230 and the first protective layer 220 may be formed of photosensitive polyimide but may be formed of photosensitive polyimide containing different materials.

A metal seed layer 240 may be arranged over the electrode pad 210 and the second protective layer 230. Specifically, the metal seed layer 240 may be arranged conformally over an upper surface of the electrode pad 210 exposed from the second protective layer 230, and on a side surface and a part of an upper surface of the second protective layer 230. For example, the metal seed layer 240 may not cover an entirety of the upper surface of the second protective layer 230. The metal seed layer 240 may be formed by a chemical vapor deposition process or a physical vapor deposition process to have a thickness of approximately 100 Å to approximately 0.5 μm. The metal seed layer 240 may be formed of a metal such as copper (Cu), nickel (Ni), titanium (Ti), tungsten (W), tin (Sn), or silver (Ag), or an alloy thereof, and may have a single layer structure or a multilayer structure.

The metal seed layer 240 may function as a seed for forming the redistribution structure 250. Further, the metal seed layer 240 may provide a path through which a current flows when the redistribution structure 250 is formed by an electro-plating process such that the redistribution structure 250 may be formed above the metal seed layer 240. Because the metal seed layer 240 is associated with the redistribution structure 250, the metal seed layer 240 may be variously applied depending on materials and configurations of the metal seed layer 240 and the redistribution structure 250.

As illustrated in FIG. 2B, the metal seed layer 240 and the redistribution structure 250 are each formed as a single layer, in some exemplary embodiments of the inventive concept, the metal seed layer 240 and the redistribution structure 250 may be formed of the same material. For example, the metal seed layer 240 may be formed of copper (Cu), and the redistribution structure 250 may also be formed of copper (Cu), in this case, the metal seed layer 240 and the redistribution structure 250 may appear as an integrated structure.

The redistribution structure 250 may include a single metal layer or multiple metal layers. For example, the redistribution structure 250 may be formed of copper (Cu), nickel (Ni), gold (Au), chromium (Cr), titanium (Ti), or palladium (Pd), or an alloy thereof. The redistribution structure 250 may be formed by an electroplating process.

The redistribution structure 250 may include a redistribution pad 2501 having a quadrangular shape and a redistribution line 250B having a line shape in contact with one side surface of the redistribution pad 250A. An entirety of the redistribution pad 250A may overlap the electrode pad 210, and a part of the redistribution line 250B may overlap the electrode pad 210.

The redistribution structure 250 may be in contact with the metal seed layer 240 over the electrode pad 210 and the second protective layer 230. For example, the redistribution structure 250 may be arranged conformally over the upper surface of the electrode pad 210 exposed from the second protective layer 230, and on the side surface and a part of the upper surface of the second protective layer 230. For example, the redistribution structure 250 may not cover an entirety of the second protective layer 230, as illustrated in FIG. 2B. Accordingly, the redistribution structure 250 may be in contact with the side surface of the second protective layer 230 and to be spaced apart from the side surface of the first protective layer 220. In addition, a thickness of the redistribution structure 250 may be greater than the sum of a thickness of the first protective layer 220 and a thickness of the second protective layer 230 in a third direction (Z direction).

Here, structural characteristics of the, redistribution structure 250 will be described in more detail. A width 210W of the electrode pad 210 in the first directions (X direction) may be formed to be greater than the greatest width 250W of the redistribution structure 250 in the first direction (X direction). This may be caused by formation of the second protective layer 230. In addition, the first width 220W of the first opening 220H in the first direction (X direction) is equal to or greater than the greatest width 250W of the redistribution structure 250 in the first direction (X direction). Further, the second width 230W of the second opening 230H in the first direction (X direction) is less than the greatest width 250W of the redistribution structure 250 in the first direction (X direction). Accordingly, a distance 250D (as illustrated in FIG. 2A) between the redistribution structures 250 adjacent to each other may be greater than or equal to approximately 10 μm. In an exemplary embodiment of the inventive concept, a distance between the redistribution pads 250A adjacent to each other may be approximately 10 μm.

The external connection member 320 may include a solder ball or a solder bump. In some exemplary embodiments of the inventive concept, a lead free solder containing tin (Sn) may be used as a material of the external connection member 320. The semiconductor package 10 may be connected to an external device such as a printed circuit board (PCS) through the external connection member 320. The external connection member 320 may be electrically connected to the redistribution structure 250 through the external connection pad 310.

A pitch between adjacent electrode pads may be particularly small where the current semiconductor packages are manufactured by a fine process, and thus, it is more difficult to form the redistribution structure by forming a pattern by a photolithography process and an etching process. In addition, since a general semiconductor package has a larger planar area of the redistribution structure covering the electrode pad than a planar area of the electrode pad, a distance between the adjacent redistribution structures is relatively small, and thus, it is more difficult to form a redistribution structure having a high reliability.

According to some exemplary embodiments of the inventive concept, the semiconductor package 10 may be configured to solve the above problem. For example, the redistribution structure 250 may be formed by forming the second protective layer 230 surrounding the first protective layer 220 on an upper surface of the electrode pad 210 and the distance 2501 between the redistribution structures 250 adjacent to each other may be further increased. In addition, a test process (e.g., an electrical die sorting (EDS) test) performed on the semiconductor chip 100 is performed in a step prior to forming the second protective layer 230 after the first protective layer 220 is formed, and thus, an exposed region of the electrode pad 210 may be sufficiently obtained in the test process. For example, the first protective layer 220 is formed before the EDS test, and the, second protective layer 230 is formed after the EDS test.

In an exemplary embodiment of the inventive concept, a distance between the electrode pads 210 adjacent to each other is less than a distance between the redistribution pads 250A adjacent to each other.

Additionally, according to some exemplary embodiments of the inventive concept, the semiconductor package 10 may contribute to an increase in reliability of the FO-WLP structure because a thickness of a buffer layer arranged under the redistribution structure 250 is increased. For example, not only the first protective layer 220 but also the second protective layer 230 are arranged under the redistribution structure 250. Thus, a thickness of the buffer layer is increased, which may reduce a physical difference such as a coefficient of thermal expansion between an external device and the semiconductor chip 100. Accordingly, the semiconductor package 10 has an increased structural reliability.

According to some exemplary embodiments of the inventive concept, the semiconductor package 10 increases in reliability and productivity.

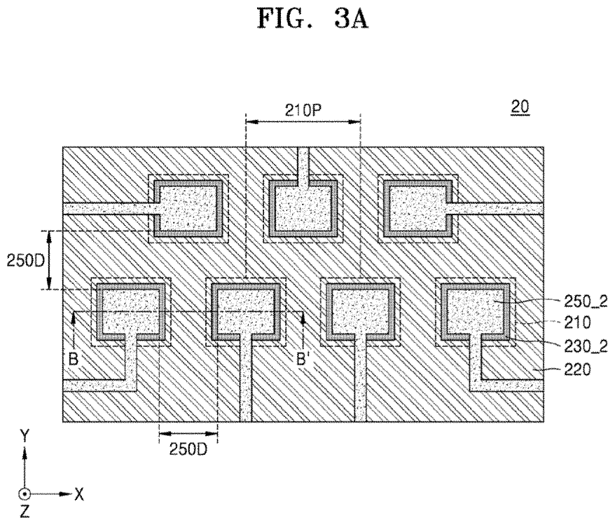

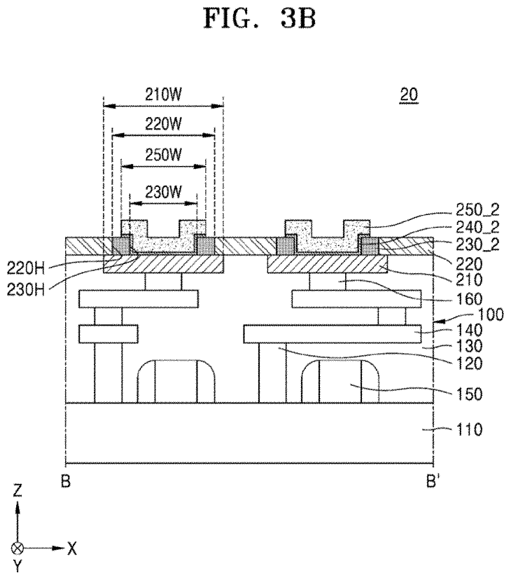

FIG. 3A is a plan view illustrating a semiconductor package according to an exemplary embodiment of the inventive concept, and FIG. 3B is a cross-sectional view taken along line B-B′ of FIG. 3A.

Most of configuration elements of the semiconductor package 20 as described below and materials of the configuration elements are substantially the same as or similar to the configuration elements and materials described above with reference to FIGS. 1 to 2B. Accordingly, for convenience of illustration, a difference between the semiconductor package 20 and the semiconductor package 10 described above will be mainly described.

Referring to FIGS. 3A and 3B, the semiconductor package 20 includes the electrode pad 210 arranged on an upper surface of the semiconductor chip 100, the first protective layer 220 surrounding edges of the electrode pads 210, a second protective layer 230_2 formed on a side surface of the first protective layer 220, and a redistribution structure 250_2 electrically connected to the electrode pad 210.

The second protective layer 230_2 is formed on the side surface of the first protective layer 220 and has the second opening 230H having the second width 230W above the electrode pad 210. The second protective layer 2302 may cover just the side surface of the first protective layer 220. For example, an entirety of an upper surface of the first protective layer 220 may be exposed. Accordingly, a level of an uppermost surface of the second protective layer 230_2 may be substantially the same as the level of the uppermost surface of the first protective layer 220.

According to an exemplary embodiment of the inventive concept, the second protective layer 230_2 may overlap just a portion of an upper surface of the electrode pad 210. Hence, a portion of the upper surface of the electrode pad 210 may be exposed. In sonic cases, with regard to the upper surface of the electrode pad 210, a width of the portion being exposed in the first direction (X direction) is greater or equal to a width of the portion being overlapped by the second protective layer 230_2 in the first direction (X direction).

A metal seed layer 240_2 may be arranged on the electrode pad 210 and the second protective layer 230_2. For example, the metal seed layer 240_2 may be arranged conformally on the upper surface of the electrode pad 210 exposed from the second protective layer 230_2, and on a side surface and a portion of an upper surface of the second protective layer 230_2.

The redistribution structure 250_2 may be in contact with the metal seed layer 240_2 on the electrode pad 210 and the second protective layer 230_2. For example, the redistribution structure 250_2 may be arranged conformally over the upper surface of the electrode pad 210 exposed from the second protective layer 230_2, and over the side surface and a portion of the upper surface of the second protective layer 230_2. In an exemplary embodiment, the redistribution structure 250_2 may overlap a portion of the upper surface of the electrode pad 210, and may overlap a portion of the upper surface of the second protective layer 230_2. Accordingly, the redistribution structure 250_2 may be in contact with the side surface of the second protective layer 230_2 and may be spaced apart from the side surface of the first protective layer 220. For example, the redistribution structure 250_2 may not make contact with the side surface of the first protective layer 220. In addition, a thickness of the redistribution structure 250_2 may be greater than each of a thickness of the first protective layer 220 and a thickness of the second protective layer 230_2 in the third direction (Z direction).

Here, structural characteristics of the redistribution structure 250_2 will be described in more detail. As illustrated in FIG. 3B, the width 210W of the electrode pad 210 in the first direction (X direction) may be greater than a greatest width 250W of the redistribution structure 250_2 in the first direction (X direction). This may be caused by formation of the second protective layer 230_2. That is, the first width 220W of the first opening 220H in the first direction (X direction) may be equal to or greater than the greatest width 250W of the redistribution structure 250_2 in the first direction (X direction). In addition, the second width 230W of the second opening 230H in the first direction (X direction) may be less than the greatest width 250W of the redistribution structure 250_2 in the first direction (X direction). According to an exemplary embodiment of the inventive concept, a thickness of the second protective layer 230_2 formed on the upper surface of the first protective layer 220 may not be considered in the semiconductor package 20.

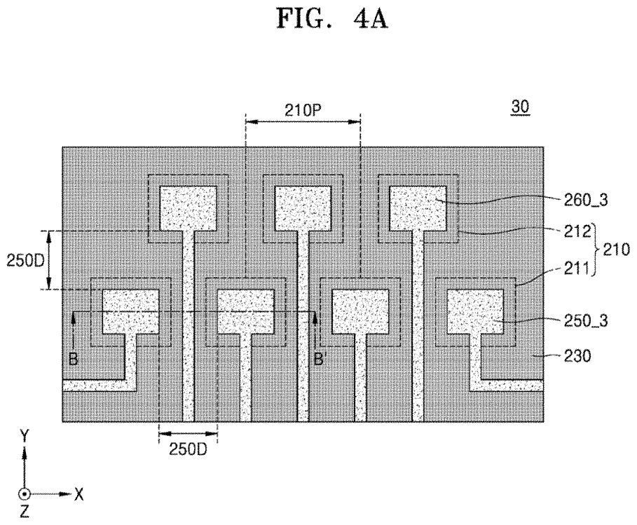

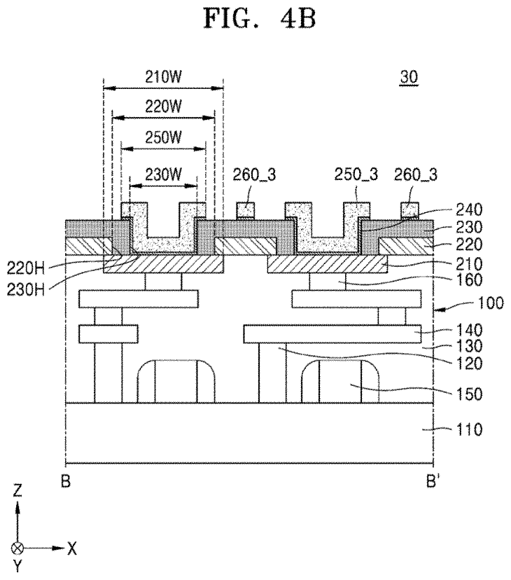

FIG. 4A is a plan view illustrating a semiconductor package according to an exemplary embodiment of the inventive concept, and FIG. 4B is a cross-sectional view taken along line B-B′ of FIG. 4A.

Most of die configuration elements of a semiconductor package 30 as described below and materials of the configuration elements are substantially the same as or similar to the configuration elements and materials described above with reference to FIGS. 1 to 2B. Accordingly, for convenience of description, a difference between the semiconductor package 30 and the semiconductor package 10 described above will be mainly described herein.

Referring to FIGS. 4A and 4B, the semiconductor package 30 includes the electrode pad 210 arranged on an upper surface of the semiconductor chip 100, the first protective layer 220 surrounding edges of the electrode pad 210, the second protective layer 230 surrounding the first protective layer 220, a first redistribution structure 250_3, and a second redistribution structure 260_3. According to an exemplary embodiment of the inventive concept, the first protective layer 220 may overlap just a portion of an upper surface of the electrode pad 210. In addition, the width of the portion being overlapped by the first protective layer 220 may be smaller than the width of a portion that is not being overlapped by the first protective layer 220.

As illustrated in FIG. 4A, the electrode pad 210 may include a first column electrode pad 211 and a second column electrode pad 212 spaced apart from the first column electrode pad 211 in the second direction (Y direction). In addition, the electrode pads 210 may each have the first pitch 210P in the first direction (X direction) and the second direction (Y direction) parallel to the upper surface of the semiconductor chip 100 and are spaced apart from each other.

The first redistribution structure 250_3 may be electrically connected to the first column electrode pad 211, and the second redistribution structure 260_3 may be electrically connected to the second column electrode pad 212. A redistribution line of the second redistribution structure 260_3 may pass between the first redistribution structures 250_3 adjacent to each other.

According to the exemplary embodiments of the inventive concept, in the semiconductor package 30, a space or area through which a redistribution line of the second redistribution structure 260_3 passes may be larger between the first redistribution structures 250_3 adjacent to each other. The larger space or area may be achieved through forming the second protective layer 230 surrounding the first protective layer 220 on an upper surface of the electrode pad 210 and designing the distance 250D between the redistribution structures 250 adjacent to each other to be further increased (e.g., as illustrated in FIG. 4A, the redistribution structures 250 adjacent to each other may be known as the first redistribution structure 250_3 and the second redistribution structure 260_3). Accordingly, in the semiconductor package 30, path disposition of the first redistribution structure 250_3 and the second redistribution structure 260_3 may be designed in a more flexible manner.

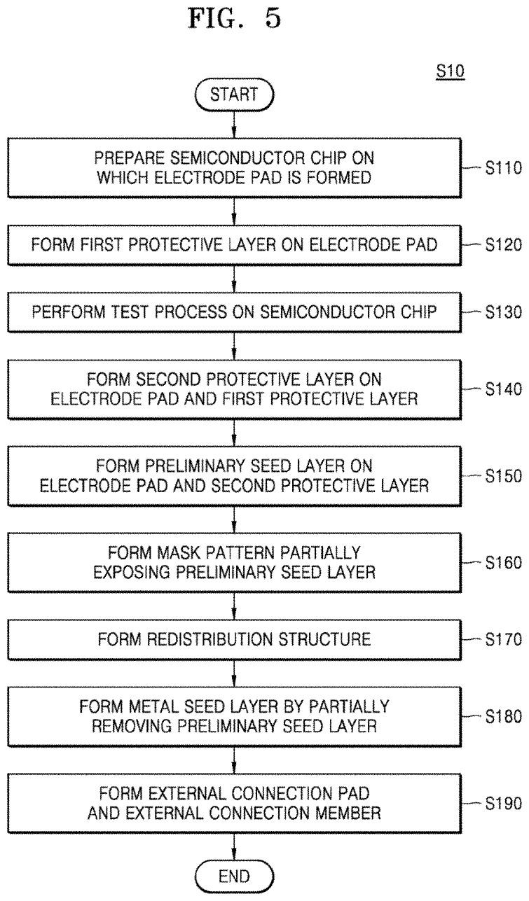

FIG. 5 is a flowchart illustrating a method of manufacturing a semiconductor package, according to an exemplary embodiment of the inventive concept.

Referring to FIG. 5, a method 810 of manufacturing a semiconductor package may include a process sequence of first to ninth steps S110 to S190.

When a certain embodiment is implemented differently, a specified process sequence may be performed differently from a sequence to be described. For example, two processes to be described in succession may be performed substantially simultaneously or in a reverse order.

According to an exemplary embodiment of the inventive concept, the method S10 of manufacturing the semiconductor package may include a first step S110 of preparing a semiconductor chip on which an electrode pad is formed, a second step S120 of forming a first protective layer on the electrode pad, a third step S130 of performing a test process on the semiconductor chip, a fourth step S140 of forming a second protective layer on the electrode pad and the first protective layer, a fifth step S150 of forming a preliminary seed layer on the electrode pad and the second protective layer, a sixth step S160 of forming a mask pattern exposing a part of the preliminary seed layer, a seventh step S170 of forming a redistribution structure, an eighth step S180 of forming a metal seed layer by removing a part of the preliminary seed layer, and a ninth step S190 of forming an external connection pad and an external connection member.

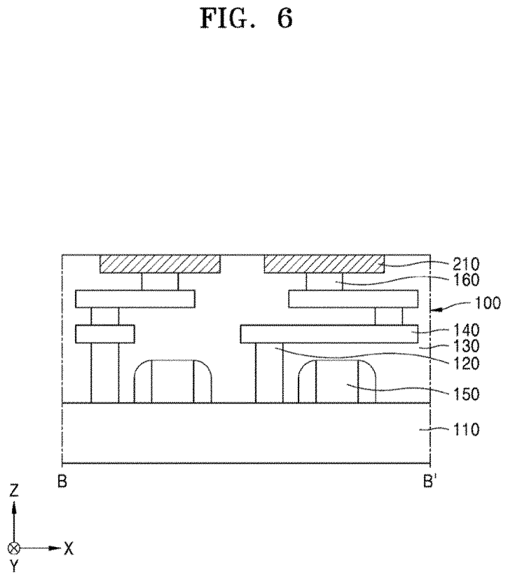

Technical characteristics of each of the nine steps (S110 to S190) will be described in detail with reference to FIGS. 6 to 13 as described below.

FIGS. 6 to 13 are cross-sectional views illustrating the method of manufacturing the semiconductor package, according to an exemplary embodiment of the inventive concept and a process sequence.

Referring to FIG. 6, the semiconductor chip 100 is prepared in which the electrode pad 210 is formed. The electrode pad 210 may be capable of expanding an integrated circuit function of the individual unit element 150 formed on the semiconductor substrate 110 to the outside.

The semiconductor substrate 110 may include a semiconductor wafer in which a plurality of semiconductor chips 100 arranged in a matrix are separated from each other by a scribe lane.

The semiconductor substrate 110 may include, for example, silicon. Alternatively, the semiconductor substrate 110 may include a semiconductor element such as germanium, or a compound semiconductor such as silicon carbide (SiC), gallium arsenide (GaAs), indium arsenide (InAs), and indium phosphide (InP). Alternatively, the semiconductor substrate 110 may have a silicon on insulator (SOI) structure. For example, the semiconductor substrate 110 may include a buried oxide layer. The conductor substrate 110 may include a conductive region, for example, a well doped with impurities or a structure doped with impurities. In addition, the semiconductor substrate 110 may have various element isolation structures such as a shallow trench isolation (STI) structure.

The semiconductor substrate 110 may include a circuit portion including the individual unit element 150 for implementing an integrated circuit function of the semiconductor element through a semiconductor manufacturing process. For example, the semiconductor substrate 110 may include the individual unit element 150, such as a transistor, a resistor, or a capacitor, a wiring layer such as the conductive via 120, the conductive wire 140, and then the upper via 160, and the interlayer insulating film 130 arranged therebetween.

In some exemplary embodiments of the inventive concept, the interlayer insulating film 130 may include a low-k material layer (as used herein, the term “low-k” is understood to mean a material having lower permittivity than silicon oxide). For example, a dielectric material forming the interlayer insulating film 130 may be oxide such as phosphor silicate glass (PSG), boro-phosphor silicate glass (BPSG), undoped silicate glass (USG), tetra ethyl ortho silicate (TEOS), plasma enhanced-TEOS (PE-TEOS), high density plasma-chemical vapor deposition (HDP-CVD) oxide, a low-k material used in BEOL, an ultra low-k material, or so on.

In some exemplary embodiments of the inventive concept, the interlayer insulating film 130 may have a structure in which a first interlayer insulating layer, a second interlayer insulating layer, a third interlayer insulating layer, and a fourth interlayer insulating layer are sequentially stacked. However, the number of interlayer insulating layers forming the interlayer insulating film 130 is not limited thereto.

The interlayer insulating film 130 may fill peripheries of the wiring layers such as the conductive via 120 and the conductive wire 140 which are formed of a conductive material. In addition, the interlayer insulating film 130 may fill peripheries of the electrode pad 210 and the upper via 160, which is in direct contact with the electrode pad 210 and is electrically connected thereto.

The electrode pad 210 may be electrically connected to the circuit portion of the semiconductor chip 100 to perform a function of electrically connecting the semiconductor chip 100 to an external electric device. The electrode pad 210 may be electrically connected to the conductive via 120 and the conductive wire 140 in a lower portion of the semiconductor chip 100 through the upper via 160 thereof.

The electrode pad 210 may be a portion for receiving and outputting an electrical signal from and to the semiconductor chip 100, may be provided on the semiconductor chip 100 in plural, and may include aluminum (Al), tungsten (W), copper (Cu), nickel (Ni), or a combination thereof. The electrode pad 210 may be formed of a metal such as aluminum (Al) on the semiconductor chip 100 in a specified thickness, and then, patterning a desirable shape of the electrode pad 210 by a photolithography process and an etching process.

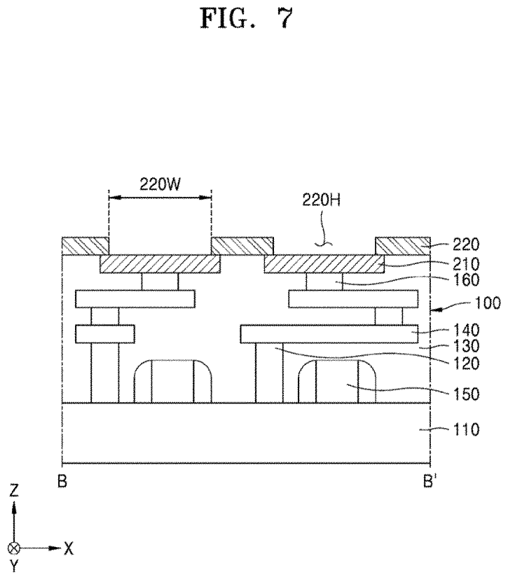

Referring to FIG. 7, the first protective layer 220 having the first opening 220H on the electrode pad 210 may be formed on the semiconductor chip 100.

After forming a preliminary protective layer on the electrode pad 210 and the semiconductor chip 100, the preliminary protective layer is patterned by a photolithography process and an etching process to form the first protective layer 220 including the first opening 220H exposing a central portion of the electrode pad 210. In an exemplary embodiment of the inventive concept, the first protective layer 220 may overlap a portion of the upper surface of the electrode pad 210.

The electrode pad 210 may be partially exposed by the first protective layer 220, which is a last protective layer of the circuit portion of the semiconductor chip 100. The electrode pad 210 may be electrically connected to the circuit portion of the semiconductor chip 100 through the upper via 160 and may be electrically connected to an external electric device through a portion of the electrode pad 210 exposed by the first opening 220H. The first width 220W of the first opening 220H of the first protective layer 220 in the first direction (X direction) may be substantially the same as a size or a width of the exposed portion of a general electrode pad 210 in the first direction (X direction).

The first protective layer 220 may be arranged above the semiconductor chip 100 to insulate the semiconductor chip 100 in a region other than the electrode pad 210. In addition, the first protective layer 220 may protect the upper surface of the semiconductor chip 100 from external impurities, chemical damage, physical impact, and etc. In some exemplary embodiments, the first protective layer 220 may include a plurality of material layers.

Referring to FIG. 8, a test process may be performed on the semiconductor chip 100 on which the first protective layer 220 is formed, by using a test apparatus TA.

The test process may be performed to verify a function and an electrical connection of the semiconductor chip 100. In some exemplary embodiments, the test process may be an electrical die sorting (EDS) test. The test process may include, for example, a DC test, an AC test, and/or a functional test. However, the test process is not limited thereto.

The test apparatus TA may include a needle-shaped test pin TP, and the test pin TP may come into physical contact with the electrode pad 210 to perform the test process. Where the first protective layer 220 is formed on the electrode pad 210, the exposed region of the electrode pad 210 that is contacted by the test pin TP may be sufficient to allow for the performance of the test process.

The contact-type test process may have a better test performance compared to a non-contact type test process. The test pin TP may include, for example, a pan of a probe card connected to the test apparatus TA. In addition, a plurality of test pins TP may be arranged on the probe card.

As a result, a subsequent process may be performed on the semiconductor chip 100 selected as having successfully completing the test process.

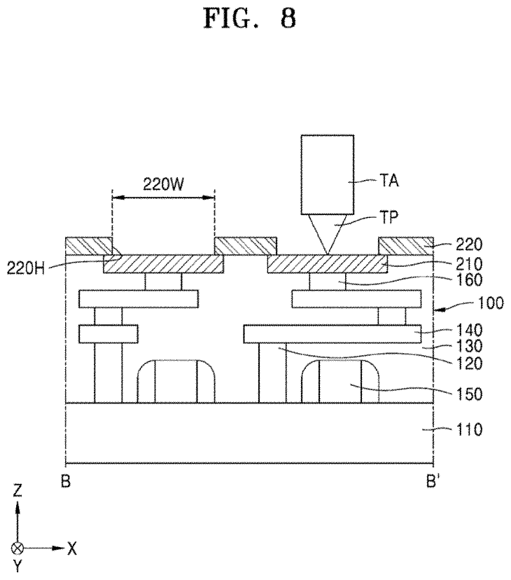

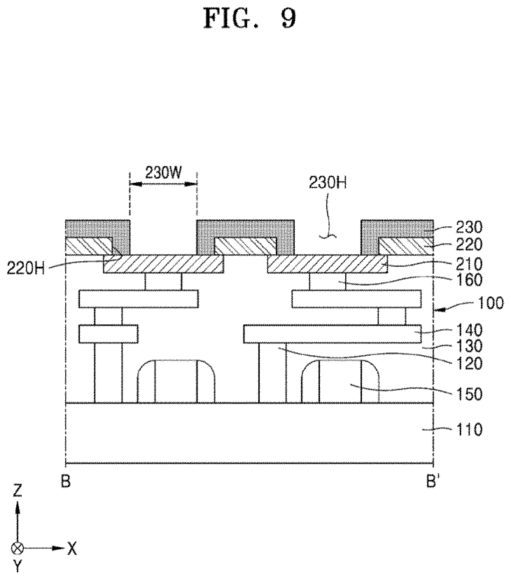

Referring to FIG. 9, the second protective layer 230 having the second opening 230H may be formed on the electrode pad 210 and the first protective layer 220.

After a preliminary protective layer is formed on the electrode pad 210 and the first protective layer 220, the preliminary protective layer is patterned by a photolithography process and an etching process. Thus, the second protective layer 230 having the second opening 230H exposing a central portion of the electrode pad 210 may be formed.

The second protective layer 230 may cover an entirety of the side surfaces and an entirety of the upper surface of the first protective layer 220. Accordingly, a level of an uppermost surface of the second protective layer 230 may be higher than a level of an uppermost surface of the first protective layer 220. Because of the second protective layer 230, the exposed region of the electrode pad 210 may be reduced compared to having only the first protective layer 220 formed.

In some exemplary embodiments of the inventive concept, the second protective layer 230 surrounds the first protective layer 220 and has the second opening 230H having a second width 230W above the electrode pad 210.

The second protective layer 230 may also be formed of an insulating material in the same manner as the first protective layer 220. In some exemplary embodiments, the second protective layer 230 may be formed of a material that is different from a material of the first protective layer 220. In other exemplary embodiments, the second protective layer 230 may also be formed of the same material as the first protective layer 220.

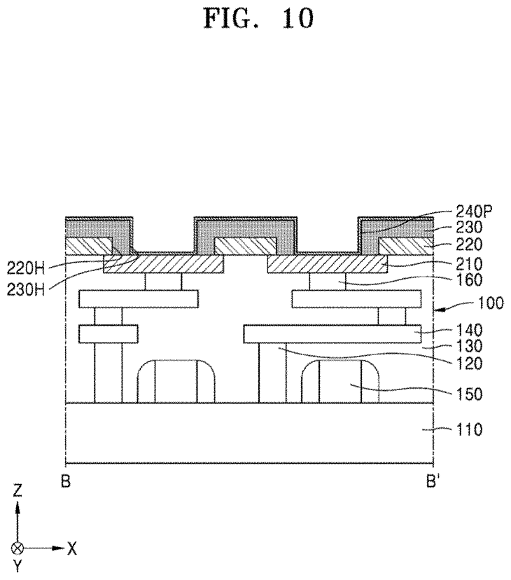

Referring, to FIG. 10, a preliminary seed layer 240P is formed on the electrode pad 210 and the second protective layer 230.

The preliminary seed layer 240P may be formed over an upper surface of the exposed electrode pad 210 and a whole surface of the second protective layer 230 and may be formed by a chemical vapor deposition process or a physical vapor deposition process to have a thickness from approximately 100 Å to approximately 0.5 μm. For example, the preliminary seed layer 240P may overlap or cover a portion of the upper surface of the exposed electrode pad 210. In addition, the preliminary seed layer 240P may cover an entirety of all sides and an entirety of upper surface of the second protective layer 230 The preliminary seed layer 240P may be formed of a metal such as copper (Cu), nickel (Ni), titanium (Ti), tungsten (W), tin (Sn), or silver (Ag), or an alloy thereof, and may have a single layer structure or a multilayer structure.

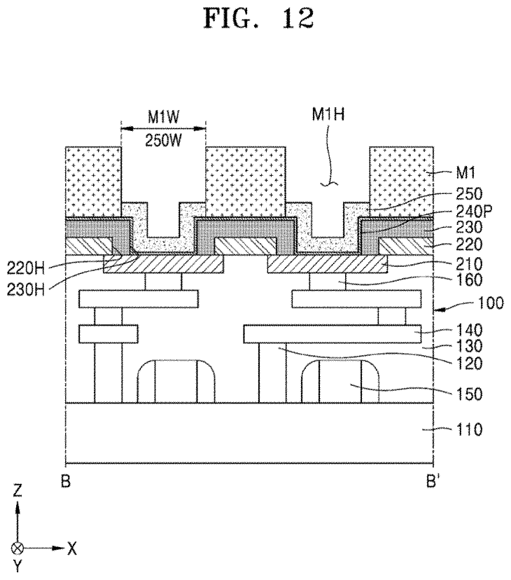

The preliminary seed layer 240P functions as a seed for a subsequent process. Further, the preliminary seed layer 240P may provide a path through which a current flows in an electroplating process, and thus, the redistribution structure 250 (see FIG. 12) may be formed above the preliminary seed layer 240P. The preliminary seed layer 240P may be formed to conformally cover the second opening 230H of the second protective layer 230.

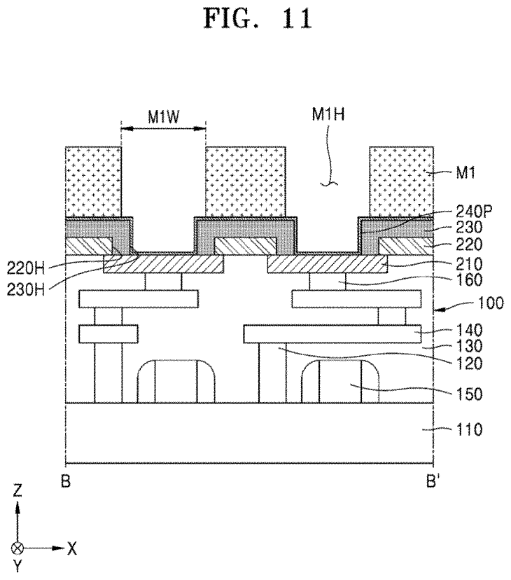

Referring to FIG. 11, a mask pattern M1 having a pattern hole M1H exposing a part of the preliminary seed layer 240P may be formed on the preliminary seed layer 240P.

A part of the preliminary seed layer 240P to be exposed may include a portion in contact with the electrode pad 210. The portion exposed by the pattern hole M1H of the mask pattern M1 may correspond to a portion where the redistribution structure 250 (see FIG. 12) will be formed in a subsequent process. Therefore, when a plurality of the electrode pads 210 are formed, the portion of the mask pattern M1 exposed by the pattern hole M1H may be formed in plurality corresponding to the respective electrode pads 210.

Referring to FIG. 12, the redistribution structure 250 may be formed on the preliminary seed layer 240P on which the mask pattern M1 is formed.

The redistribution structure 250 may be in direct contact with an upper surface of the preliminary seed layer 240P exposed by the pattern hole M1H of the mask pattern M1. The redistribution structure 250 may be formed by an electroplating process.

In some exemplary embodiments of the inventive concept, in order to form the redistribution structure 250, the semiconductor substrate 110 on which the mask pattern M1 is formed may be placed in a bath to perform electroplating therefor. The redistribution structure 250 may be formed of, for example, one metal selected from copper (Cu), nickel (Ni), and gold (Au) or may be formed of an alloy thereof or may have a multilayer structure of a plurality of metals selected from copper (Cu), nickel (Ni), and gold (Au).

The redistribution structure 250 may fill just a part of a region exposed by, the pattern hole M1H of the mask pattern M1 without filling the whole of the mask pattern M1. In an exemplary embodiment of the inventive concept, a thickness of the redistribution structure 250 in the third direction (Z direction) may be thinner than the mask pattern M1 in the third direction (Z direction). A width M1W of the pattern hole M1H of the mask pattern M1 in the first direction (X direction) may be substantially the same as the greatest width 250W of the redistribution structure 250 in the first direction (X direction).

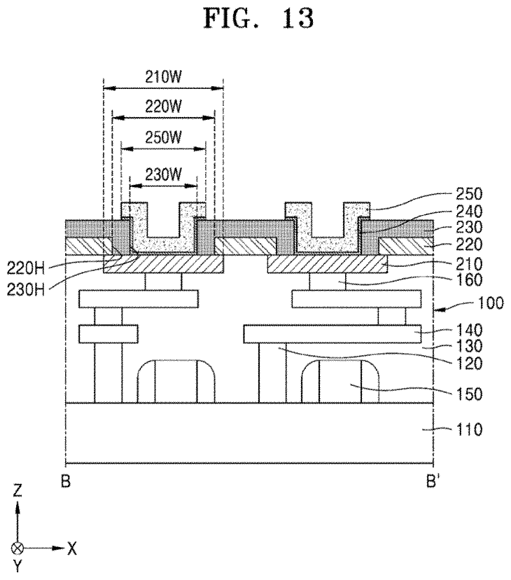

Referring to FIG. 13, after the mask pattern M1 manufacturing step (see FIG. 12), a part of the preliminary seed layer 240P (see FIG. 12) may be removed to form the metal seed layer 240.

In order to remove the mask pattern M1 (see FIG. 12), a strip process and/or an ashing process may be performed, in some exemplary embodiments, after the mask pattern M1 (see FIG. 12) is removed, the preliminary seed layer 240P (see FIG. 12) exposed to the outside is wet-etched by using the redistribution structure 250 as an etching mask. When the preliminary seed layer 240P (see FIG. 12) is etched by using wet etching which is isotropic etching, undercut may be formed under the redistribution structure 250. In other exemplary embodiments, the preliminary seed layer 240P (see FIG. 12) exposed to the outside may be dry-etched by using the redistribution structure 250 as an etching mask.

When a configuration material of the preliminary seed layer 240P (see FIG. 12) is copper (Cu), the preliminary seed layer 240P may be removed by ammoniacal etching. For example, alkaline etchants including Cu(NH₃)₄Cl₂, Cu(NH₃)₂Cl, NH₃, and NH₄Cl may be used. Subsequently, chemicals containing CuO obtained as a result of the etching may be cleaned by using and H₂O.

Through these processes, the width 210W of the electrode pad 210 in the first direction (X direction) may be formed to be greater than the greatest width 250W of the redistribution structure 250 in the first direction (X direction). This may be obtained by forming the second protective layer 230. For example, the first width 220W of the first opening 220H in the first direction (X direction) may be equal to or greater than the greatest width 250W of the redistribution structure 250 in the first direction (X direction). In addition, the second width 230W of the second opening 230H in the first direction (X direction) is less than the greatest width 250W of the redistribution structure 250 in the first direction (X direction).

Referring back to FIG. 1, the external connection pad 310 may be formed on the redistribution structure 250, and the external connection member 320 may be formed on the external connection pad 310. As a result, the semiconductor package 10 according to exemplary embodiments of the inventive concept may be manufactured.

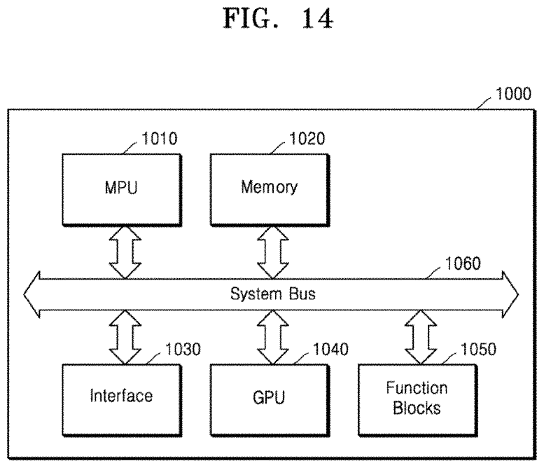

FIG. 14 is a configuration diagram schematically illustrating a configuration of a semiconductor package according to an exemplary embodiment of the inventive concept.

Referring to FIG. 14, a semiconductor package 1000 may include a micro processing unit (MPU) 1010, a memory 1020, an interface 1030, a graphic processing unit (GPU) 1040, functional blocks 1050, and a bus 1060 being connected thereto. The semiconductor package 1000 may include both the micro processing unit 1010 and the graphic processing unit 1040 or may include only one of the two units.

The micro processing unit 1010 may include a core and a cache. For example, the micro processing unit 1010 may include multiple cores. The multiple cores may have the same performance or different performances. In addition, the multiple cores may be activated simultaneously or may be activated at different time points.

The memory 1020 may store results and the like obtained by processing of the functional blocks 1050 under a control of the micro processing unit 1010. The interface 1030 may transmit or receive information or signals to and from an external device. The graphic processing unit 1040 may perform graphic functions. For example, the graphic processing unit 1040 may perform video codec or may process 3D graphics. The functional blocks 1050 may perform various functions. For example, when the semiconductor package 1000 is an application processor used in a mobile device, some of the functional blocks 1050 may perform a communication function.

The semiconductor package 1000 may include any one of the semiconductor packages 10, 20, and 30 described with reference to FIGS. 1 to 4B.

While the inventive concept has been particularly show and described with reference to the exemplary embodiments thereof, it will be understood by one of ordinary skill in the art that variations in form and detail may be made therein without departing from the spirit and scope of the inventive concept as defined by the following claims.

What is claimed is:

1. A semiconductor package, comprising:
an electrode pad arranged in a first direction parallel to an upper surface of a semiconductor chip;
a first protective layer at least partially surrounding an edge of the electrode pad and having a first opening that is above the electrode pad;
a second protective layer at least partially surrounding the first protective layer and having a second opening that is above the electrode pad; and
a redistribution structure electrically connected to the electrode pad and covering at least a part of an upper surface of the second protective layer,
wherein a first width of the first opening in the first direction is equal to or greater than a maximum width of the redistribution structure in the first direction, and
wherein a second width of the second opening in the first direction is less than the maximum width of the redistribution structure in the first direction.

2. The semiconductor package of claim 1, wherein the second protective layer covers an entirety of a side surface and an entirety of an upper surface of the first protective layer, and
wherein a level of an uppermost surface of the second protective layer is higher than a level of an uppermost surface of the first protective layer.

3. The semiconductor package of claim 1, wherein the second protective layer covers a side surface of the first protective layer and does not cover an upper surface of the first protective layer, and
wherein a level of an uppermost surface of the second protective layer is substantially the same as a level of an uppermost surface of the first protective layer.

4. The semiconductor package of claim 1, wherein a material forming the first protective layer and a material forming the second protective layer are different from each other.

5. The semiconductor package of claim 1, wherein a width of the electrode pad in the first direction is greater than the maximum width of the redistribution structure in the first direction.

6. The semiconductor package of claim 1, wherein the redistribution structure comprises a redistribution pad having a quadrangular shape and a redistribution line having a line shape, and
wherein, in a plan view,
an entirety of the redistribution pad overlaps the electrode pad, and
a part of the redistribution line overlaps the electrode pad.

7. The semiconductor package of claim 6, wherein the electrode pad comprises a first column electrode pad and a second column electrode pad spaced apart from the first column electrode pad in a second direction perpendicular to the first direction, and
wherein the redistribution line of the redistribution structure arranged on the second column electrode pad passes through a space between the first column electrode pads adjacent to each other.

8. The semiconductor package of claim 1, wherein a thickness of the redistribution structure is greater than the sum of a thickness of the first protective layer and a thickness of the second protective layer.

9. The semiconductor package of claim 1, wherein the first protective layer has a bridge shape connecting the electrode pads adjacent to each other.

10. The semiconductor package of claim 1, wherein the redistribution structure is in contact with a side surface of the second protective layer and is spaced apart from a side surface of the first protective layer.

11. A semiconductor package, comprising:
a plurality of aluminum pads arranged on a semiconductor chip, spaced apart from each other with a first pitch therebetween in a first direction;
a first polymer layer at least partially surrounding edges of the aluminum pads and having first openings respectively formed above the aluminum pads;
a second polymer layer at least partially surrounding the first polymer layer and having second openings respectively formed above the aluminum pads;
a metal seed layer conformally covering upper surfaces of the aluminum pads, side surfaces of the second polymer layer, and a part of upper surfaces of the second polymer layer;
redistribution pads spaced apart from each other with the first pitch and conformally covering the metal seed layer; and
redistribution lines extending from one side surface of the redistribution pads and each having a line shape,
wherein a first width of the first opening in the first direction is greater than a maximum width of the redistribution pad in the first direction, and
wherein a second width of the second opening in the first direction is less than the maximum width of the redistribution pad in the first direction.

12. The semiconductor package of claim 11, wherein the first pitch is approximately 60 μm, and
wherein the first width of the first opening is approximately 40 μm.

13. The semiconductor package of claim 11, wherein a distance between the aluminum pads adjacent to each other is less than a distance between the redistribution pads adjacent to each other.

14. The semiconductor package of claim 11, wherein the distance between the redistribution pads adjacent to each other is approximately 10 μm.

15. The semiconductor package of claim 11, wherein the first polymer layer is formed before an electrical die sorting (EDS) test, and
wherein the second polymer layer is formed after the EDS test.

16. A semiconductor package, comprising:
a semiconductor chip including an electrode pad arranged in a first direction;
a redistribution region arranged under the semiconductor chip;
a molding member extending from the redistribution region and at least partially surrounding the semiconductor chip; and
an external connector arranged under the redistribution region,
wherein the redistribution region comprises:
a first protective layer at least partially surrounding an edge of the electrode pad and having first opening above the electrode pad;
a second protective layer at least partially surrounding the first protective layer and having a second opening above the electrode pad; and
a redistribution structure electrically connected to the electrode pad and covering at least a part of an upper surface of the second protective layer,
wherein a first width of the first opening in the first direction is equal to or greater than a maximum width of the redistribution structure in the first direction, and
wherein a second width of the second opening in the first direction is less than the maximum width of the redistribution structure in the first direction.

17. The semiconductor package of claim 16, wherein the redistribution structure comprises a redistribution pad having a quadrangular shape and a redistribution line having a line shape,
wherein, in a plan view,
an entirety of the redistribution pad overlaps the electrode pad, and
a part of the redistribution line overlaps the electrode pad.

18. The semiconductor package of claim 17, wherein the electrode pad comprises a first column electrode pad and a second column electrode pad spaced apart from the first column electrode pad in a second direction perpendicular to the first direction, and
wherein the redistribution line of the redistribution structure arranged on the second column electrode pad passes through a space between the first column electrode pads adjacent to each other.

19. The semiconductor package of claim 16, wherein, in a plan view, an area occupied by the redistribution region is greater than an area occupied by the semiconductor chip.

20. The semiconductor package of claim 19, wherein the semiconductor package includes a wafer level package.
